(19) United States
(12) Patent Application Publication
(10) Pub. No.: US 2025/0119080 A1
(43) Pub. Date: Apr. 10, 2025

(54) ELECTROSTATIC CHUCK

(71) Applicant: TOTO LTD., Fukuoka (JP)

(72) Inventors: Masafumi IKEGUCHI, Fukuoka (JP); Kouta KOBAYASHI, Fukuoka (JP); Yutaka MOMIYAMA, Fukuoka (JP)

(73) Assignee: TOTO LTD., Fukuoka (JP)

(21) Appl. No.: 18/896,477

(22) Filed: Sep. 25, 2024

(30) Foreign Application Priority Data
Oct. 10, 2023 (JP) 2023-175472

(51) Int. Cl. H02N 13/00; B23Q 3/15

(52) U.S. Cl. CPC H02N 13/00; B23Q 3/15

(57) ABSTRACT

An electrostatic chuck 10 includes a dielectric substrate 100 in which through-holes 140 are formed, a base plate 200 formed of a metal material, and a bonding layer 300 that bonds the dielectric substrate 100 and the base plate 200. When a Young's modulus of the bonding layer 300 is E (MPa), and a distance between a central axis AX0 of the dielectric substrate 100 and a central axis AX1 of each of the through-holes 140 is X (mm), with respect to the through-holes 140 at a position farthest from the central axis AX0, E≤0.2063×X²−59.3887×X+4278.8065 is established.

### CROSS-REFERENCE TO RELATED APPLICATION

This application is based upon and claims the benefit of priority from Japanese Patent Application No. 2023-175472 filed on Oct. 10, 2023, the entire contents of which are incorporated herein by reference.

### TECHNICAL FIELD

The present invention relates to an electrostatic chuck.

### BACKGROUND

For example, a semiconductor manufacturing apparatus such as an etching apparatus is provided with an electrostatic chuck as an apparatus for attracting and holding a substrate such as a silicon wafer to be an object to be processed. The electrostatic chuck includes a dielectric substrate provided with a chucking electrode, and a base plate that supports the dielectric substrate, and has a configuration in which the dielectric substrate and the base plate are bonded to each other. When a voltage is applied to the chucking electrode, an electrostatic force is generated, and a substrate placed on the dielectric substrate can be attracted and held.

During processing, the temperature of the substrate rises because the substrate is exposed to plasma, and the temperature of the dielectric substrate also rises. On the other hand, the base plate is supplied with a low temperature refrigerant, and therefore, the temperature of the base plate may be lowered to a temperature of −60° C. or less. Due to a temperature change of each part following processing of the substrate, a temperature difference between the dielectric substrate and the base plate, and the like, a great thermal stress is applied to the dielectric substrate.

In order to prevent damage to the dielectric substrate due to the thermal stress, it is necessary to select a material having suitable physical properties, as the material of a bonding layer that connects the dielectric substrate and the base plate. For example, Japanese Patent Laid-Open No. 2020-23088 proposes to set a storage modulus of the bonding layer (adhesion member) at −60° C. to 100 MPa or less, and the like.

### SUMMARY

If a material with the smallest possible Young's modulus is used as the material of the bonding layer, the thermal stress applied to the dielectric substrate can be reduced to be small. However, in view of heat transfer performance and the like required for the bonding layer, the Young's modulus of the bonding layer cannot be made as small as possible. The material of the bonding layer needs to be properly selected in consideration of the required heat transfer performance and the like under the condition that the Young's modulus is a predetermined upper limit value or less.

However, in the dielectric substrate, through-holes for the purpose of supplying cooling gas or the like are formed. According to the experiments and the like conducted by the present inventors, there has been obtained the knowledge that the thermal stress applied to the dielectric substrate becomes particularly large in the portions of the through-holes, and the magnitude thereof changes according to the positions of the through-holes. Specifically, when the distance between the central axis of the dielectric substrate and the central axis of the through-hole is X, the thermal stress applied to the portion of the through-hole becomes larger as the value of X becomes larger. In other words, the larger the value of X is, the narrower the upper limit value of the range allowable with respect to the Young's modulus of the bonding layer can be.

Accordingly, in order to suppress the thermal stress applied to the dielectric substrate while satisfying the required specifications such as the heat transfer performance, it is necessary to properly set parameters of “the distance between the central axis of the dielectric substrate and the central axis of the through-hole”, and “the upper limit value of the Young's modulus of the bonding layer”, while considering a correlation of “the distance between the central axis of the dielectric substrate and the central axis of the through-hole”, and “the upper limit value of the Young's modulus of the bonding layer”. However, up until now, no concrete study has been conducted on matters such as how the correlation of them should be taken into account.

The present invention is made in view of this sort of problem, and an object of the present invention is to provide an electrostatic chuck that can optimize a value of a Young's modulus of a bonding layer and reduce thermal stress applied to a dielectric substrate.

In order to solve the above-described problem, an electrostatic chuck according to the present invention includes a dielectric substrate in which through-holes are formed, a base plate formed of a metal material, and a bonding layer that bonds the dielectric substrate and the base plate. In this electrostatic chuck, when a Young's modulus of the bonding layer is E (MPa), and a distance between a central axis of the dielectric substrate and a central axis of each of the through-holes is X (mm), with respect to the through-holes at a position farthest from the central axis of the dielectric substrate, E≤0.2063×X²−59.3887×X+4278.8065 is established.

The through-holes at the position farthest from the central axis of the dielectric substrate are the portions to which the greatest thermal stress is applied in the dielectric substrate in many cases. According to the experiments and the like conducted by the present inventors, there has been obtained the knowledge that if the position (X) of the through-holes and the Young's modulus (E) of the bonding layer are respectively set so as to satisfy the condition of E≤0.2063×X²−59.3887×X+4278.8065, the thermal stress in the through-hole portions of the dielectric substrate can be sufficiently reduced. By configuring the electrostatic chuck as described above, it is possible to reduce the thermal stress applied to the dielectric substrate while optimizing the value of the Young's modulus of the bonding layer and the like.

The above-described equation concerning the Young's modulus of the bonding layer may be established with respect to not only the through-holes at the position farthest from the central axis of the dielectric substrate but also all the through-holes formed in the dielectric substrate.

According to the present invention, it is possible to provide the electrostatic chuck capable of optimizing the value of the Young's modulus of the bonding layer and reducing the thermal stress applied to the dielectric substrate.

### BRIEF DESCRIPTION OF DRAWINGS

FIG. 1 is a sectional view schematically showing a configuration of an electrostatic chuck according to a present embodiment.

FIG. 2 is a view showing a configuration of a dielectric substrate included by the electrostatic chuck in FIG. 1.

FIG. 3 is a view showing an actual shape of the electrostatic chuck according to the present embodiment.

FIG. 4 is a diagram showing a relationship between a Young's modulus of a bonding layer and maximum stress generated in the dielectric substrate.

FIG. 5 is a diagram showing a relationship between a position of a through-hole and an allowable Young's modulus.

### DETAILED DESCRIPTION

Hereinafter, the present embodiment will be described with reference to the accompanying drawings. To make the explanation easier to understand, the same components are assigned the same reference signs in each of the drawings as many as possible, and redundant explanation is omitted.

An electrostatic chuck 10 according to the present embodiment attracts and holds a substrate W to be an object to be processed by an electrostatic force inside a semiconductor manufacturing apparatus, not shown in figures, such as an etching apparatus, for example. The substrate W is, for example, a silicon wafer. The electrostatic chuck 10 may be used in apparatuses other than semiconductor manufacturing apparatuses.

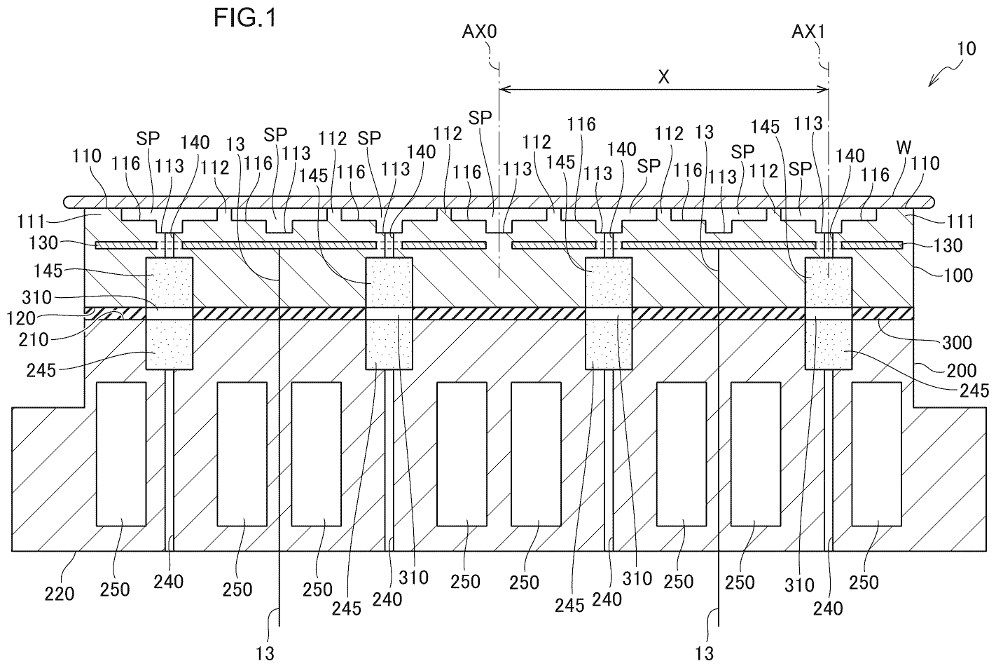

FIG. 1 shows a configuration of the electrostatic chuck 10 in a state of attracting and holding the substrate W as a schematic sectional view. The electrostatic chuck 10 includes a dielectric substrate 100, a base plate 200, and a bonding layer 300.

The dielectric substrate 100 is a substantially disk-shaped member made of a sintered ceramic body. The dielectric substrate 100 contains, for example, high-purity aluminum oxide (Al₂O₃), but may contain other materials. The purity, type, additives, and the like of the ceramics in the dielectric substrate 100 can be appropriately set in consideration of plasma resistance and the like required for the dielectric substrate 100 in the semiconductor manufacturing apparatus.

A surface 110 on an upper side in FIG. 1 of the dielectric substrate 100 serves as a “placement surface” on which the substrate W is placed. A surface 120 on a lower side in FIG. 1 in the dielectric substrate 100 serves as a “bonded surface” bonded to the base plate 200 via the bonding layer 300 described later. A viewpoint when the electrostatic chuck 10 is viewed from a surface 110 side along a direction perpendicular to the surface 110 is also expressed below as a “top view”. A thickness of the dielectric substrate 100, that is, a distance between the surface 110 and the surface 120 is 0.9 mm in the present embodiment but may be a thickness different from this.

A chucking electrode 130 is buried inside the dielectric substrate 100. The chucking electrode 130 is a thin plane tabular layer formed of a metal material such as tungsten, for example, and disposed to be parallel to the surface 110. As a material of the chucking electrode 130, molybdenum, platinum, palladium, and the like may be used in addition to tungsten. When a voltage is applied to the chucking electrode 130 from outside via a power supply path 13, an electrostatic force is generated between the surface 110 and the substrate W, and thereby the substrate W is attracted and held. Two chucking electrodes 130 may be provided as so-called “bipolar” electrodes as in the present embodiment, but only one of them may be provided as a so-called “monopolar” electrode.

In FIG. 1, the entire power supply path 13 is drawn by being simplified. A portion inside the dielectric substrate 100 of the power supply path 13 is configured as, for example, an elongated via (hole) filled with a conductor, and an electrode terminal not shown is provided at a lower end thereof. In the power supply path 13, a portion penetrating the base plate 200 described later is a conductive metal member (for example, a bus bar) to which one end of the electrode terminal described above is connected. In the base plate 200, a through-hole, not shown in figures, for inserting the power supply path 13 is formed. For example, a cylindrical insulating member may be provided between an inner surface of the through-hole and the power supply path 13.

As shown in FIG. 1, a space SP is formed between the dielectric substrate 100 and the substrate W. When a process such as etching is performed in the semiconductor manufacturing apparatus, helium gas for temperature adjustment is supplied to the space SP from outside via a through-hole 140 or the like described later. As a result of helium gas being interposed between the dielectric substrate 100 and the substrate W, thermal resistance between both of them is adjusted, and the temperature of the substrate W is thereby kept at a suitable temperature. Note that the gas for temperature adjustment supplied to the space SP may be gas of a different type from helium.

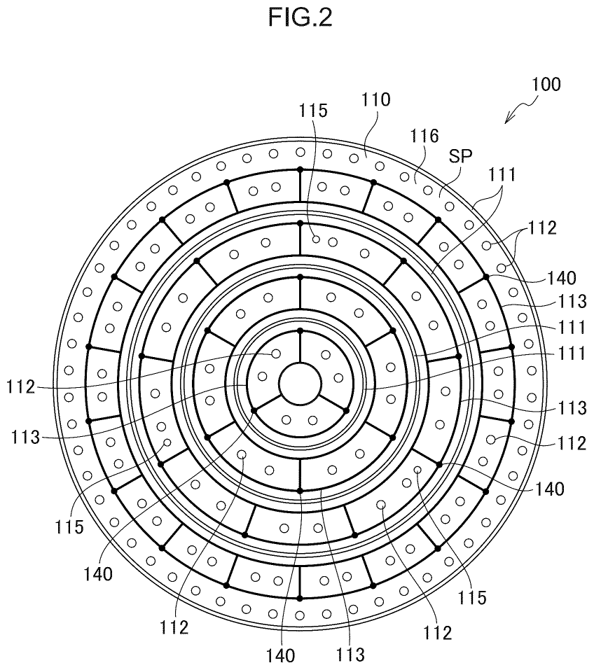

FIG. 2 is a view of the dielectric substrate 100 drawn in top view. As shown in the drawing, seal rings 111 and dots 112 are provided on the surface 110 serving as the placement surface, and the above-described space SP is formed around them.

The seal ring 111 is a wall that divides the space SP, and a plurality of seal rings 111 are provided to be aligned concentrically in top view. An upper end of each of the seal rings 111 is a part of the surface 110, and abuts on the substrate W. In the present embodiment, a total of four seal rings 111 are provided, and thereby the space SP is divided into four. With the configuration like this, it is possible to individually adjust pressure of helium gas in each part of the respective spaces SP and make a surface temperature distribution of the substrate W during processing closer to uniform.

Portions assigned the reference sign “116” in FIG. 1 and FIG. 2 are bottom surfaces of the space SP. Each of these portions is also referred as a “bottom surface 116” below. The seal ring 111 is formed as a result of part of the surface 110 being dug to a position of the bottom surface 116, with the dots 112 described next.

The dot 112 is a circular protrusion that protrudes from the bottom surface 116. As shown in FIG. 2, a plurality of dots 112 are provided, and dispersed and disposed substantially uniformly on the placement surface of the dielectric substrate 100. An upper end of each of the dots 112 is part of the surface 110, and abuts the substrate W. By providing a plurality of such dots 112, bending of the substrate W is suppressed.

A groove 113 is formed on the bottom surface 116 of the space SP. The groove 113 is a groove formed to be retracted further from the bottom surface 116 to a surface 120 side. The groove 113 is formed for the purpose of quickly dispersing helium gas supplied from the through-hole 140 into the space SP and making a pressure distribution in the space SP substantially uniform in a short time. Note that the groove 113 can be removed depending on the number and disposition of the through-holes 140.

In the dielectric substrate 100, the through-hole 140 that extends perpendicularly to the surface 110 side from the surface 120 is formed. As shown in FIG. 2, an end portion on the surface 110 side of the through-hole 140 is opened in a bottom surface of the groove 113. In the dielectric substrate 100, a plurality of through-holes 140 are formed, and these through-holes 140 are aligned along the grooves 113. In the present embodiment, a plurality of through-holes 140 are connected to each part of the spaces SP divided into four.

Note that in FIG. 2, a diameter of the through-hole 140 is drawn as larger than a width of the groove 113 for convenience of illustration, but as shown in FIG. 1, the diameter of the actual through-hole 140 is smaller than the width of the groove 113. In order to contain the through-hole 140 inside the groove 113, the width of the groove 113 may be locally large in the position of the through-hole 140. A diameter in an end portion (that is, an end portion on the surface 110 side) on an opposite side to the bonding layer 300, of the through-hole 140 is 0.2 mm or less in the present embodiment.

As shown in FIG. 1, a portion on the surface 120 side, of the through-hole 140, is enlarged in diameter as compared with the portion on the surface 110 side, and a ventilation plug 145 is disposed inside thereof. The ventilation plug 145 is a porous body formed of an alumina, for example, and entirely has air permeability. As a result of the ventilation plug 145 like this being disposed inside the through-hole 140, it is possible to suppress occurrence of dielectric breakdown in a path through the through-hole 140 while ensuring a flow of gas in the through-hole 140. Note that when dielectric breakdown can be sufficiently prevented, a configuration in which no ventilation plug 145 is disposed in the through-hole 140 may be adopted. In this case, an inside diameter of the through-hole 140 may be uniform entirely in an up-down direction.

What is assigned the reference sign “115” in FIG. 2 is a through-hole through which a lift pin (not illustrated in figures) and provided in the semiconductor manufacturing apparatus is inserted. The through-hole is also referred to as a “through-hole 115” below. The through-hole 115 is formed to extend perpendicularly from the surface 120 to the surface 110 side similarly to the above-described through-hole 140. A total of three through-holes 115 are formed, and these through-holes are disposed at equal intervals of 120 degrees. By lift pins that move up and down through the through-holes 115, the substrate W is attached to and detached from the surface 110 of the dielectric substrate 100.

The base plate 200 is a substantially disk-shaped member that supports the dielectric substrate 100. The base plate 200 is formed of a metal material such as an aluminum, for example. In the base plate 200, a surface 210 on an upper side in FIG. 1 serves as a “bonded surface” that is bonded to the dielectric substrate 100 via the bonding layer 300.

As shown in FIG. 1, in the base plate 200, a through-hole 240 extending perpendicularly from the surface 210 to a surface 220 side on an opposite side to the surface 210 is formed. The through-hole 240 is formed at each of positions that overlap the through-holes 140 of the dielectric substrate 100 in top view, and is caused to communicate with the through-hole 140 via a through-hole 310 provided in the bonding layer 300. The through-hole 240 is a part of the path for supplying helium gas to the space SP, with the through-hole 140 of the dielectric substrate 100.

As shown in FIG. 1, a portion on the surface 210 side, of the through-hole 240 is enlarged in diameter as compared with a portion on a surface 220 side, and a ventilation plug 245 is disposed inside thereof. The ventilation plug 245 is a porous body formed of an alumina, for example, and entirely has air permeability. As a result of the ventilation plug 245 like this being disposed inside of the through-hole 240, it is possible to suppress occurrence of dielectric breakdown in a path through the through-hole 240 while ensuring a flow of gas in the through-hole 240. Note that when dielectric breakdown can be sufficiently prevented, a configuration in which no ventilation plug 245 is disposed in the through-hole 240 may be adopted. In this case, an inside diameter of the through-hole 240 may be made uniform entirely in the up-down direction.

Although the through-hole 240 may be formed to entirely extend rectilinearly as in the present embodiment, it may be formed to bend halfway to the surface 220. Further, a configuration may be adopted, in which a plurality of through-holes 240 on the surface 210 side are consolidated into a small number of flow paths inside the base plate 200, and the flow paths are then extended to the surface 220 side.

A refrigerant flow path 250 for passing a refrigerant is formed inside the base plate 200. When a process such as film formation is performed in the semiconductor manufacturing apparatus, a refrigerant is supplied to the refrigerant flow path 250 from outside, and thereby the base plate 200 is cooled. Heat generated in the substrate W during processing is transferred to the refrigerant via the helium gas in the space SP, the dielectric substrate 100, and the base plate 200, and then is discharged outside with the refrigerant.

A through-hole (not illustrated in figures) for passing the lift pin is formed in each of positions that overlap the through-holes 115 in top view, in the base plate 200.

An insulating film may be formed on a surface of the base plate 200. The insulating film is preferably formed over a range including at least the entire surface 210 of the surface of the base plate 200. As the insulating film, a film of alumina that is formed by thermal spraying can be used, for example. By covering the surface of the base plate 200 with the insulating film, it is possible to enhance a dielectric withstand voltage of the base plate 200.

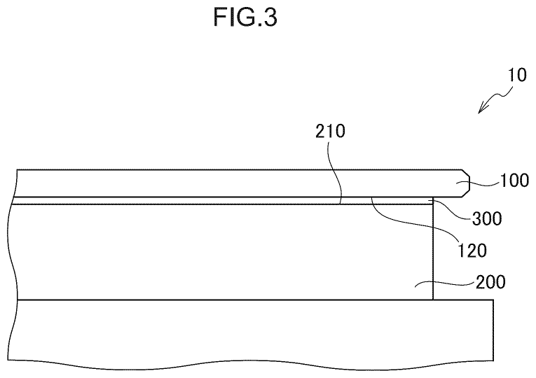

Note that in FIG. 1, a diameter of the surface 120 of the dielectric substrate 100, and a diameter of the surface 210 of the base plate 200 are schematically drawn as equal to each other, but both of them are often different from each other. FIG. 3 shows an actual configuration of the electrostatic chuck 10. As shown in the drawing, in the electrostatic chuck 10 of the present embodiment, the diameter of the surface 120 of the dielectric substrate 100 is slightly larger than the diameter of the surface 210 of the base plate 200. Accordingly, an outer peripheral side portion of the dielectric substrate 100 protrudes toward outside than the base plate 200 and is not supported from a lower side. However, the configuration like this is only an example, and a configuration in which the respective above-described diameters correspond to each other may be adopted.

The bonding layer 300 is a layer provided between the dielectric substrate 100 and the base plate 200 and bonds both of them. The bonding layer 300 is obtained by curing an adhesive material made of an insulating material. In the present embodiment, a silicone adhesive is used as the above-described adhesive. However, the bonding layer 300 may be made by curing other types of adhesives. In any case, as the material of the bonding layer 300, it is preferable to use a material having as high a thermal conductivity as possible so as to reduce thermal resistance between the dielectric substrate 100 and the base plate 200. A configuration in which a plurality of particulate bulking agents (fillers) for enhancing heat conductivity are disposed inside the bonding layer 300 may be adopted. As the bulking agents, particles containing an alumina as a main component can be used, for example.

A thickness of the bonding layer 300 can be appropriately set according to heat transfer performance or the like required for the bonding layer 300. In the present embodiment, the thickness of the bonding layer 300 is 250 μm but may be a thickness different from this. Note that there may be the cases where the thickness of the bonding layer 300 is not entirely uniform, such as a case where electrode terminals are buried in the surface 120 side of the dielectric substrate 100, a case where a groove is formed in a part of the surface 210 of the base plate 200, and the like. The “thickness of the bonding layer 300” in that case is a thickness of a range except for the portions where the thickness is locally different from that of the other portion as described above.

The bonding layer 300 has a small Young's modulus (modulus of longitudinal elasticity) as compared with the dielectric substrate 100 and the base plate 200. Even if a thermal expansion difference occurs between the dielectric substrate 100 and the base plate 200, the bonding layer 300 deforms and absorbs the thermal expansion difference, so that it is possible to suppress thermal stress to be small in the dielectric substrate 100 and the like.

The Young's modulus of the bonding layer 300 changes according to the temperature of the bonding layer 300. A numeric value expressing a Young's modulus of the bonding layer 300 when the temperature of the bonding layer 300 is −60° C. in a unit of “MPa” is described as “E” below. For example, when the Young's modulus of the bonding layer 300 at −60° C. is 0.01 GPa, E=10. Note that the temperature of “−60° C.” in the above description is merely a convenient standard for identifying the physical properties (Young's modulus) of the bonding layer 300 and does not place any limitations on the temperature or the like of the refrigerant that is actually supplied to the refrigerant flow path 250.

In recent years, with increase in energy entering the substrate W during processing and the like, there has been a trend toward requiring the base plate 200 to have higher cooling performance than before. For example, a refrigerant having a temperature of −60° C. or less may be supplied to the refrigerant flow path 250 of the base plate 200. As the temperature of the refrigerant will become even lower with increase in output power of plasma and the like, it may be possible to supply refrigerants at around −100° C. in the future.

Large thermal stress is applied to the dielectric substrate 100 due to a temperature change in each part accompanying the start of processing of the substrate W, the temperature difference between the dielectric substrate 100 and the base plate 200, and the like. According to the experiments and the like conducted by the present inventors, there has been obtained the knowledge that the thermal stress applied to the dielectric substrate 100 particularly increases in the portions of the through-holes (exit portions of the through-holes 140, for example), and a magnitude thereof changes according to the positions of the through-holes.

For convenience of explanation, a central axis of the dielectric substrate 100 is also referred to as a “central axis AX0” below (see FIG. 1). The central axis AX0 is an axis that passes through the center of the dielectric substrate 100 that is circular in top view, and is perpendicular to the surface 110. Note that an orientation flat or the like is formed in a part of the outer periphery side of the dielectric substrate 100, for example, and the shape of the dielectric substrate 100 in top view may not be strictly circular. In this case, it is assumed that the above-described orientation flat or the like is not formed, the entire shape of the dielectric substrate 100 is considered to be circular, and then the central axis AX0 is defined as the axis passing through the center of the circle.

Further, a central axis of the through-hole 140 is also referred to as a “central axis AX1” below (see FIG. 1). As described above, the through-hole 140 is the hole formed to extend perpendicularly to the surface 110 side from the surface 120. Accordingly, the central axis AX1 is the axis perpendicular to the surface 110 similarly to the central axis AX0. The central axis AX1 is individually defined for each of the plurality of through-hole 140.

A numeric value expressing a distance from the central axis AX0 of the dielectric substrate 100 to the central axis AX1 of the through-hole 140 in a unit of “mm” is described as “X” or a “distance X” below. The distance X is individually defined for each of the plurality of through-holes 140. According to the experiments and the like conducted by the present inventors, there is a tendency that as the distance X from the central axis AX0 to the central axis AX1 of the through-hole 140 increases, a magnitude of the thermal stress applied to the portion of the through-hole 140 also increases. In other words, in the dielectric substrate 100, the largest thermal stress is applied to the portions of the through-holes 140 formed at the outermost periphery in many cases.

If a material with as small a Young's modulus as possible is used as the material of the bonding layer 300, the thermal stress applied to the dielectric substrate 100 can be suppressed to be small. However, in view of the heat transfer performance and the like required for the bonding layer 300, the Young's modulus of the bonding layer 300 cannot be made as small as possible. It may be needed to appropriately select the material of the bonding layer 300 in consideration of the required heat transfer performance and the like under the condition that the Young's modulus is a predetermined upper limit value or less.

As the distance X from the central axis AX0 of the dielectric substrate 100 to the central axis AX1 of the through-hole 140 is smaller, the thermal stress applied to the portion of the through-hole 140 becomes smaller, and therefore, an upper limit value of the Young's module (E) that is allowable increases. In this way, the position (X) of the through-hole 140 and the upper limit value of the Young's modulus (E) of the bonding layer 300 are parameters that are correlated with each other. The present inventors have been able to obtain the new knowledge as shown below concerning the above-described correlation by conducting various experiments, analyses, and the like.

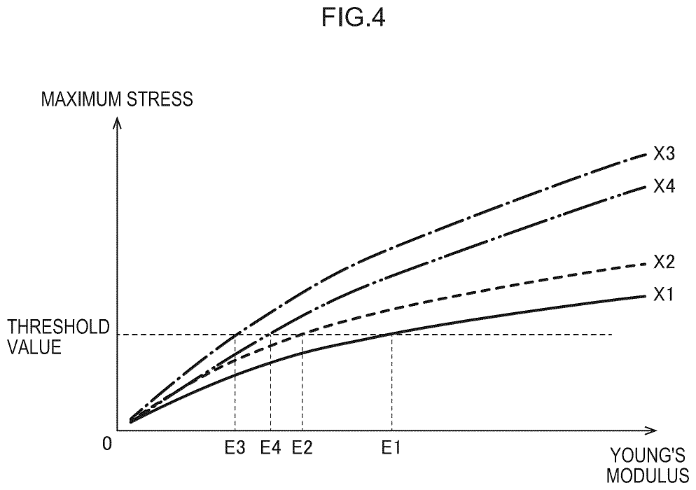

Four graphs shown in FIG. 4 each show a relationship between the Young's modulus of the bonding layer 300 at −60° C. (horizontal axis), and the maximum stress generated in the dielectric substrate 100 (vertical axis).

For example, the graph assigned “X1” on the right side was obtained by performing analysis at each time with respect to the dielectric substrate 100 in which the through-hole 140 at the farthest position from the central axis AX0 (namely, the outermost periphery) is X=X1 while changing the value of the Young's modulus (specifically, the Young's modulus at −60° C.) of the bonding layer 300, and plotting the maximum values of the thermal stress (also referred to as the “maximum stress” below) generated in the dielectric substrate 100 at a time of a low temperature.

The “time of a low temperature” described above is a time when the temperature of the entire electrostatic chuck 10 is lowered to −60° C., after the bonding layer 300 is cured in a state where the temperature of the entire electrostatic chuck 10 is 40° C., specifically. Note that in each of the analyses, the “maximum value of the stress generated in the dielectric substrate 100” was the value of the stress generated in the portion in the vicinity of the end portion on the surface 110 side, of the through-holes 140 disposed at the outermost periphery (namely, the through-holes 140 with X=X1).

The respective graphs assigned “X2” to “X4” on the right side were also obtained based on the similar analysis to that described above. X2 is a larger distance than X1, X3 is a larger distance than X2, and X4 is a larger distance than X3.

Seeing the respective graphs in FIG. 4, it is found that as the Young's modulus of the bonding layer 300 increases, the maximum stress generated in the dielectric substrate 100 at the time of the low temperature also increases. When comparing under the condition where the Young's modulus of the bonding layer 300 is the same, it can be found that the greater the distance X of the through-hole 140 disposed at the outermost periphery is, the greater the maximum stress generated in the dielectric substrate 100 at the time of the low temperature tends to be.

However, the maximum stress at the time of X=X4 is slightly smaller than the maximum stress at the time of X=X3, which is opposite to the above-described trend. This is because the position of the through-hole 140 corresponding to X4 is the position on the outer periphery side from the surface 210 of the base plate 200, that is, the position where the lower side of the dielectric substrate 100 is not supported by the base plate 200. In reality, the possibility of the through-hole 140 being formed at the position like this is considered to be low.

A “threshold value” shown in the vertical axis in FIG. 4 is an upper limit value of a range of maximum stress that will not cause damage in the dielectric substrate 100.

In FIG. 4, “E1” is a value of the Young's modulus (E) with which the value of the maximum stress is the above-described threshold value in the dielectric substrate 100 in which the distance X of the through-hole 140 at the outermost periphery is X1. “E2” is a value of the Young's modulus (E) with which the value of the maximum stress is the above-described threshold value in the dielectric substrate 100 in which the distance X of the through-hole 140 at the outermost periphery is X2. The same also applies to “E3” and “E4”. Each of E1 to E4 can be said as the upper limit values of the range allowable as the value of the Young's modulus (E) of the bonding layer 300 so as not to cause damage to the dielectric substrate 100. The upper limit value of the Young's modulus like this is also referred to as an “allowable Young's modulus” below. As is obvious from FIG. 4, the allowable Young's modulus (E1 to E4) have different values according to the distance X (X1 to X4) of the through-holes 140 at the outermost periphery.

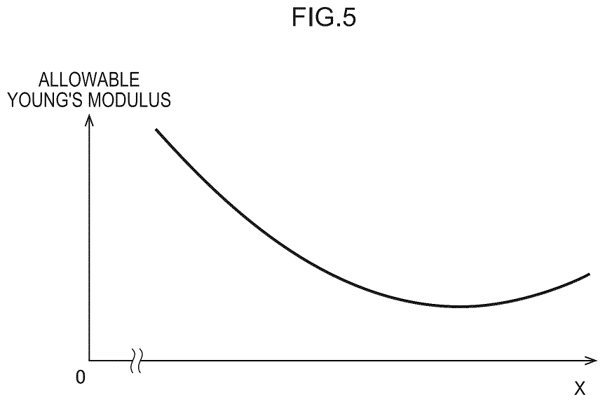

A correspondence relation between the distance X (horizontal axis) of the through-hole 140 at the outermost periphery and the allowable Young's modulus (vertical axis) is as in the graph of FIG. 5. As shown in the figure, it can be seen that there is a correlation between both of them that is roughly like a quadratic curve. As the distance X increases, the allowable Young's modulus gradually decreases. However, once the distance X increases to a certain level, the allowable Young's modulus increases conversely as the distance X increases. This tendency to increase occurs because the portion at the outermost periphery of the dielectric substrate 100 is not supported by the base plate 200 from below. The relationship between both of them shown in FIG. 5 can be expressed by equation (1) below.

$$Allowable Young ' s modulus = 0.2063 \times {X}^{2} - 59.38 \; 87 \times X + 4278.8065 \qquad ( 1 )$$

Accordingly, when E that is the Young's modulus of the bonding layer 300, and the distance X of the through-hole 140 at the outermost periphery satisfy the condition expressed by equation (2) below, the value of the maximum stress generated in the dielectric substrate 100 is within the “threshold value” in FIG. 4, and damage to the dielectric substrate 100 is reliably prevented.

$$E \leq 0. 2063 \times {X}^{2} - 59.38 \; 87 \times X + 4278.8065 \qquad ( 2 )$$

Note that for example, when the outside diameter of the dielectric substrate 100 is different from that of the present embodiment, the respective coefficients of equation (1) and equation (2) calculated by the above-described methods have strictly different values from the above accordingly. However, the “threshold value” shown in FIG. 4 is set in consideration of a certain margin, and therefore even when the configuration of the electrostatic chuck 10 is slightly different from that of the present embodiment, equation (2) can be directly used to determine.

As above, as a result of the analyses and the like conducted by the present inventors, equation (2) described above was obtained as the condition for optimizing the distance X of the through-hole 140 at the outermost periphery and the Young's modulus E of the bonding layer 300. If the positions of the through-holes 140 and the Young's modulus E of the bonding layer 300 are selected to satisfy the condition of equation (2) described above, the thermal stress of the dielectric substrate 100 during processing of the substrate W or the like can be reduced to a level that does not cause damage. Specific values of E and X can be appropriately set as the values within the ranges that satisfy the condition of (2) described above while satisfying the required specifications such as heat transfer performance required for the bonding layer 300.

Note that a group of through-holes 140 that satisfy the condition of equation (2) described above can include at least the through-hole 140 located at a position farthest from the central axis AX0 of the dielectric substrate 100, but may include the through-holes 140 at the other positions. All of the through-holes 140 formed in the dielectric substrate 100 preferably satisfy the condition of equation (2). By adopting the configuration like this, it is possible to more reliably prevent damage of the dielectric substrate 100 due to thermal stress.

Note that it has been found that the smaller the diameter in the end portion on the opposite side to the bonding layer 300 (that is, the end portion on the surface 110 side) in the through-hole 140 and the like is, the greater the thermal stress generated in the dielectric substrate 100 can be. Like the through-holes 140, through-holes for the purpose of supplying inert gas are often small holes with a diameter of 0.2 mm or less to prevent dielectric breakdown. It is confirmed by analyses and the like that by setting the thickness and the Young's modulus of the bonding layer 300 so as to satisfy the condition of equation (2) described above, thermal stress can be suppressed to such a level that does not cause damage to the dielectric substrate 100 even when the diameters of the through-holes are 0.2 mm or less. Note that the above description does not in any way deny the diameter of the through-hole being made 0.2 mm or more.

As the bonding layer 300, various types of adhesives can be used as long as the adhesives can satisfy the condition of equation (2) described above. For example, in addition to a silicone adhesive as in the present embodiment, various adhesives such as epoxy, polyimide, acrylic, and modified silicone resin can be used to form the bonding layer 300. However, since the silicone adhesive has a relatively small Young's modulus after cured, it is possible to easily select one that satisfies the condition of equation (2) described above from various types of silicone adhesives. Accordingly, the bonding layer 300 is preferably a cured silicone adhesive, as in the present embodiment.

As the adhesive for forming the bonding layer 300, an existing adhesive commercially available may be directly used, but an existing adhesive whose Young's modulus has been adjusted so as to satisfy the condition of equation (2) may be used. As a method for adjusting the Young's modulus of the adhesive, various known methods can be adopted. For example, functional groups or fillers are added to the adhesive, and by adjusting the type and adding amount of each, it is possible to change the Young's modulus in a low temperature range, such as −60 degrees, to a desired value. As one example, when the adhesive is a silicone resin, by adjusting the adding amount of a phenyl group, it is possible to adjust the Young's modulus particularly in the low temperature range. Further, by reducing the adding amount of an inorganic filler, it is also possible to reduce the Young's modulus.

As described above, the greater the distance X of the through-hole 140 is, the greater the thermal stress applied to the portion of the through-hole 140 can be. In the dielectric substrate 100 where at least one of the through-holes 140 is formed at the outer peripheral side portion where X≥75 mm, the thermal stress applied to the portion of the through-hole 140 often becomes large to a level that cannot be ignored. However, if the material of the bonding layer 300 is selected to satisfy the condition of equation (2) described above, the thermal stress can be suppressed to a level that does not cause damage to the dielectric substrate 100.

In the present embodiment, the through-holes formed on the outermost periphery side of the plurality of through-holes formed in the dielectric substrate 100 are the through-holes 140 (instead of the through-holes 115). When another through-hole is formed at a position further outward than the through-hole 140, the Young's modulus (E) of the bonding layer 300 can be set so that the position (X) of the through-hole satisfies the condition of equation (2).

The present embodiment is described thus far with reference to the specific examples. However, the present disclosure is not limited to these specific examples. These specific examples with design modifications appropriately added by a person skilled in the art are also included within the scope of the present disclosure as long as they incorporate the features of the present disclosure. The respective elements included by each of the aforementioned specific examples, and dispositions, conditions, shapes and the like of them are not limited to those illustrated but can be changed as appropriate. Combinations of the respective elements included in each of the specific examples described above can be appropriately changed as long as no technical contradiction occurs.

What is claimed is:

1. An electrostatic chuck, comprising:
a dielectric substrate in which through-holes are formed;
a base plate formed of a metal material; and
a bonding layer that bonds the dielectric substrate and the base plate,
wherein when a Young's modulus of the bonding layer is E (MPa), and
a distance between a central axis of the dielectric substrate and a central axis of each of the through-holes is X (mm),
with respect to the through-holes at a position farthest from the central axis of the dielectric substrate,
E≤0.2063×X²−59.3887×X+4278.8065 is established.

2. The electrostatic chuck according to claim 1, wherein in each of the through-holes, a diameter in an end portion on an opposite side to the bonding layer is 0.2 mm or less.

3. The electrostatic chuck according to claim 1, wherein the bonding layer is a cured silicone adhesive.

4. The electrostatic chuck according to claim 1, wherein at least one of the through-holes is formed at a position where X≥75 mm.

5. An electrostatic chuck, comprising:
a dielectric substrate in which through-holes are formed;
a base plate formed of a metal material; and
a bonding layer that bonds the dielectric substrate and the base plate,
wherein when a Young's modulus of the bonding layer is E (MPa), and
a distance between a central axis of the dielectric substrate and a central axis of each of the through-holes is X (mm),
with respect to all the through-holes,
E≤0.2063×X²−59.3887×X+4278.8065 is established.
